(19) United States
(12) Patent Application Publication
(10) Pub. No.: US 2026/0279185 A1
(43) Pub. Date: Sep. 17, 2026

(54) MONITORING SYSTEM OF CLEAN ROOM

(71) Applicant: Tokyo Electron Limited, Tokyo (JP)

(72) Inventors: Hikaru AKADA, Kumamoto (JP); Takayuki OGAMI, Kumamoto (JP)

(21) Appl. No.: 19/674,143

(22) Filed: May 12, 2026

Related U.S. Application Data
(63) Continuation of application No. PCT/JP2024/039995, filed on Nov. 11, 2024.

(30) Foreign Application Priority Data
Nov. 21, 2023 (JP) 2023-197473

(51) Int. Cl. G08B 21/22; G01R 27/14; G08B 21/18

(52) U.S. Cl. CPC G08B 21/22; G01R 27/14; G08B 21/182

(57) ABSTRACT

A monitoring system may include: a detection tape disposed on upper surfaces of some or all of floor tiles surrounding the substrate processing apparatus, the detection tape extending across a plurality of floor tiles and comprising a conductive layer disposed along a longitudinal direction of the tape; and a controller configured to generate an alarm based on electrical continuity in the conductive layer.

### CROSS-REFERENCE TO RELATED APPLICATIONS

This application is a continuation application of PCT Application No. PCT/JP 2024/039995, filed on Nov. 11, 2024, which claims the benefit of priority from Japanese Patent Application No. 2023-197473, filed on Nov. 21, 2023. The entire contents of the above listed PCT and priority applications are incorporated herein by reference.

### BACKGROUND

### Field

The present disclosure relates to a monitoring system, a monitoring method, a monitoring apparatus, and a detection tape.

### Description of the Related Art

Japanese U.S. Pat. No. 6,018,821 describes a cleanroom monitoring apparatus for monitoring the interior of a cleanroom in which a removable floor surface is disposed on a floor portion, the cleanroom monitoring apparatus including: a monitoring camera that captures images of the removable floor surface in a passage through which workers can pass; a monitoring unit that detects, from an image signal obtained by the monitoring camera, the presence or absence of an opening from which the removable floor surface has been removed, detects, from the image signal of the monitoring camera, the presence or absence of a worker approaching the opening when the opening is present, and outputs an alarm signal when the worker is detected; and an alarm generating means that receives the alarm signal from the monitoring unit and generates an alarm.

### SUMMARY

Disclosed herein is a monitoring system for monitoring surroundings of a substrate processing apparatus installed in a cleanroom. The monitoring system may include: a detection tape disposed on upper surfaces of some or all of floor tiles surrounding the substrate processing apparatus, the detection tape extending across a plurality of floor tiles and comprising a conductive layer disposed along a longitudinal direction of the tape; and a controller configured to generate an alarm based on electrical continuity in the conductive layer.

Additionally, a monitoring apparatus for monitoring surroundings of a substrate processing apparatus installed in a cleanroom is disclosed herein. The monitoring apparatus may include a controller configured to be connected to a detection tape disposed on upper surfaces of some or all of floor tiles surrounding the substrate processing apparatus, the detection tape extending across a plurality of floor tiles and comprising a conductive layer disposed along a longitudinal direction thereof, wherein the controller is configured to generate an alarm based on electrical continuity in the conductive layer.

Additionally, a detection tape used in the monitoring system is disclosed herein. The detection tape may include: an insulating base portion comprising insulating adhesive layers on a front surface and a back surface; the conductive layer provided on the front surface of the base portion and disposed along a longitudinal direction of the detection tape; an insulating non-adhesive region disposed on the front surface of the base portion along the longitudinal direction of the detection tape; and an insulating protective layer covering the conductive layer and the non-adhesive region and adhering to the base portion, wherein the detection tape is configured to be paid out from a roll-wound state.

### BRIEF DESCRIPTION OF THE DRAWINGS

FIG. 1 is a perspective view of a monitoring system.

FIG. 2 is an explanatory plan view schematically illustrating the monitoring system.

FIG. 3 is a front cross-sectional view of the detection tape as seen from the longitudinal direction.

FIG. 4 is a front cross-sectional view of a detection tape according to another configuration as seen from the longitudinal direction.

FIG. 5 is a perspective view illustrating a state in which a detection tape wound in a roll is being paid out and cut.

FIG. 6A to 6D is an explanatory view illustrating a procedure for connecting the conductive layer at the terminal end of the detection tape, wherein FIG. 6A is a plan view of the terminal end, FIG. 6B is a plan view when the protective layer at the terminal end is removed, FIG. 6C is an explanatory view illustrating a state in which a connection tape is being attached to the portion from which the protective layer has been removed, and FIG. 6D is a plan view illustrating a state after the connection tape has been attached.

FIG. 7 is a perspective view illustrating a state in which the end of the detection tape has been cut.

FIG. 8 is a perspective view illustrating a state in which the protective layer is pressed from both sides with fingertips from the state of FIG. 7.

FIG. 9 is a perspective view illustrating a state in which the protective layer is peeled up with fingertips from the state of FIG. 8.

FIG. 10 is a perspective view illustrating a state in which the peeled-up protective layer is being cut with scissors from the state of FIG. 9.

FIG. 11 is a perspective view as seen from the back surface side illustrating a state of connection between the end of the detection tape and a cable.

FIG. 12 is an explanatory view illustrating a state in which a pulse wave is transmitted from a controller to the conductive layer of the detection tape and the controller is receiving the returned pulse wave.

FIG. 13 is an explanatory view explaining the measurement status of the pulse wave in FIG. 12.

FIG. 14 is a perspective view of a monitoring system.

FIG. 15 is a perspective view illustrating a state in which a worker is cutting the detection tape in the monitoring system of FIG. 14.

FIG. 16 is a perspective view illustrating a state in which a worker has lifted a floor tile from the state of FIG. 14 in the monitoring system of FIG. 14.

FIG. 17 is a perspective view illustrating a state in which the protective layers at the ends of opposing detection tapes are each removed and a connection tape is being attached thereover.

FIG. 18 is an explanatory view schematically illustrating a side cross-section in the state of FIG. 17.

FIG. 19 is an explanatory view schematically illustrating a side cross-section illustrating a state after the connection tape has been attached from the state of FIG. 18.

FIG. 20 is a perspective view illustrating a state after the connection tape has been attached.

FIGS. 21A, B, and C is a view illustrating a state in which the conductive layers at the ends of detection tapes arranged with a direction change of 90 degrees are being connected, wherein FIG. 21A is a plan view illustrating a state in which the protective layers at the ends of two detection tapes are removed to expose the conductive layers, FIG. 21B is a bottom view of a connection tape having conductive layers provided in an angle shape, and FIG. 21C is a side cross-sectional view of the connection tape.

FIG. 22 is a plan view illustrating a state after the connection tape has been attached from the state of FIG. 21A.

### DETAILED DESCRIPTION

In the following description, with reference to the drawings, the same reference numbers are assigned to the same components or to similar components having the same function, and overlapping description is omitted.

In a semiconductor manufacturing line for manufacturing semiconductor devices, a large number of semiconductor manufacturing apparatuses such as substrate processing apparatuses are disposed in a cleanroom maintained in a clean atmosphere. In such a cleanroom, floor tiles (sometimes called grating) having a large number of lattice-shaped ventilation portions are disposed on the floor portion. In addition, piping, various electrical equipment, pumps, chemical liquid tanks, and the like are housed in the space below the floor tiles. For example, when installing, maintaining, or repairing such piping, various electrical equipment, pumps, and the like, workers may descend into the space below the floor tiles to perform work, and therefore the floor tiles are removable.

In this way, in a cleanroom, workers can descend into the space below the floor tiles with the floor tiles removed to perform work. However, when a floor tile is removed, an opening exists in the floor surface of the cleanroom formed by the large number of floor tiles, and there is a risk that workers may fall from this opening into the space below. In particular, workers performing other work on the floor tiles may be working without knowing that an opening has been formed, and it has been practiced to call workers'attention.

The technology described in Patent Literature 1 uses a monitoring camera that captures images of the floor tile surface and, based on the image signal obtained by the monitoring camera, detects the presence or absence of an opening from which a floor tile has been removed, and when a worker is present, outputs an alarm signal to generate an alarm from an alarm generating means.

Although such technology has improved the safety of workers, it requires the installation of expensive equipment such as monitoring cameras, and also requires a large number of cameras to be installed so that there are no blind spots, which involves costs and labor in the installation work itself. Therefore, the present disclosure provides a technology that may readily construct a monitoring system capable of detecting the presence or absence of an opening formed by the removal of such a floor tile. A monitoring system will be described below. Note that, elements having substantially the same functional configuration are denoted by the same reference numerals, and redundant description is omitted.

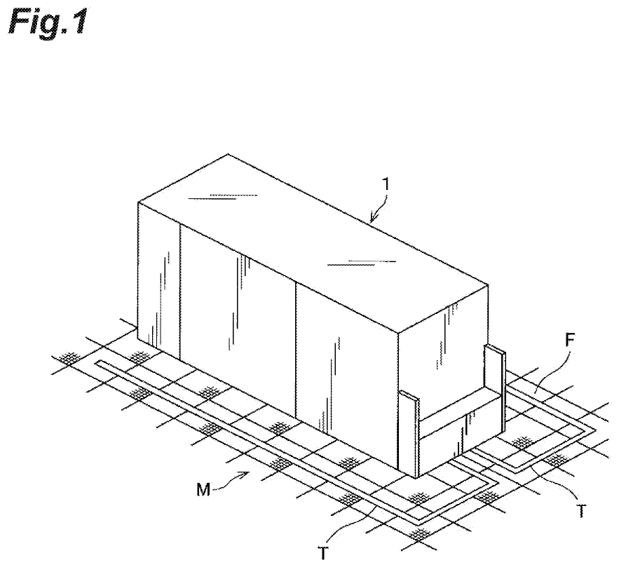

FIG. 1 illustrates a state of a monitoring system M for monitoring the surroundings of a substrate processing apparatus 1, the monitoring system M being constructed by arranging a detection tape T for the monitoring system. The substrate processing apparatus 1 is installed in a cleanroom, and floor tiles F are laid in a grid pattern on the floor surface around it. The detection tape T has a flat shape like a flat cable.

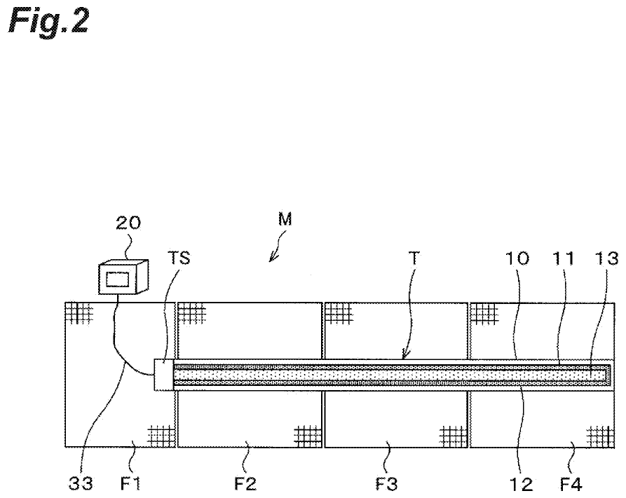

FIG. 2 is an explanatory plan view schematically illustrating a simplified monitoring system M in order to explain such a monitoring system in an understandable manner. In this example, the detection tape T is arranged extending across floor tiles F2 to F4. Each of the floor tiles F2 to F4 has, for example, a square outer shape with a side of 60 cm.

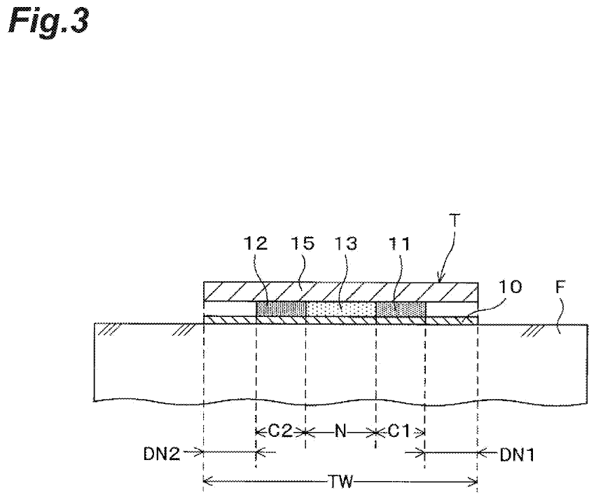

As illustrated in FIG. 3, the detection tape T has an insulating base portion 10 having insulating adhesive layers on the front and back surfaces, and conductive layers 11 and 12 provided on the front surface side of the base portion 10 and arranged in parallel along the longitudinal direction of the detection tape T. For the conductive layers 11 and 12, for example, flat copper foil can be used. In this example, the conductive layers 11 and 12 are provided in parallel with an insulating non-adhesive region 13 interposed therebetween. The non-adhesive region 13 can be realized, for example, by attaching an insulating tape, such as a peelable synthetic resin tape, to the central region of the base portion 10 in order to match the height with the thickness of the conductive layers 11 and 12.

An insulating protective layer 15 is disposed on the conductive layers 11 and 12 and the non-adhesive region 13 so as to cover them, and the protective layer 15 adheres to the base portion 10. However, since the non-adhesive region 13 is located between the conductive layers 11 and 12, the lower surface of the protective layer 15 and the non-adhesive region 13 do not adhere to each other, and this portion is peelable. Note that in this example, the width TW of the detection tape T is set to, for example, 100 mm or less so as to readily be handled. Of course, without being limited to this, the width TW of the detection tape T can be arbitrarily set, for example, between 30 mm and 100 mm, taking into account the thickness and flexibility of the protective layer 15, the width C1 of the conductive layer 11, the width C2 of the conductive layer 12, the width N of the non-adhesive region 13, and the like. The width TW of the detection tape T is not limited to this range.

In this example, the adhesive force of each portion is set such that the adhesion between the front surface side of the base portion 10 and the lower surface side of the protective layer 15 is stronger than the adhesion on the back surface side of the base portion 10, that is, the adhesion between the base portion 10 and the surface of the floor tile F. This may realize a configuration in which, for example, the base portion 10 of the detection tape T can be peeled from the surface of the floor tile F, but the protective layer 15 and the base portion 10 are not readily peeled from each other. Therefore, the detection tape T may readily be attached and detached to and from the surface of the floor tile F, and workability is good. On the other hand, the protective layer 15 and the base portion 10 are not easily peeled from each other, and exposure of the internal conductive layers 11 and 12 is suppressed.

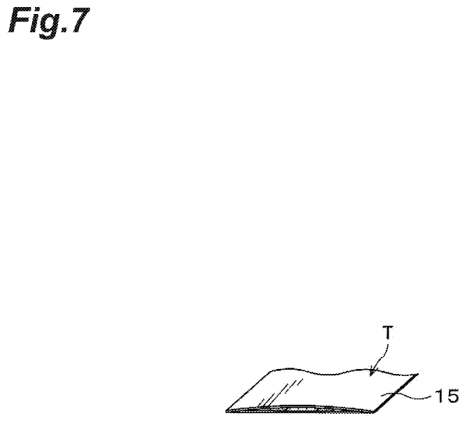

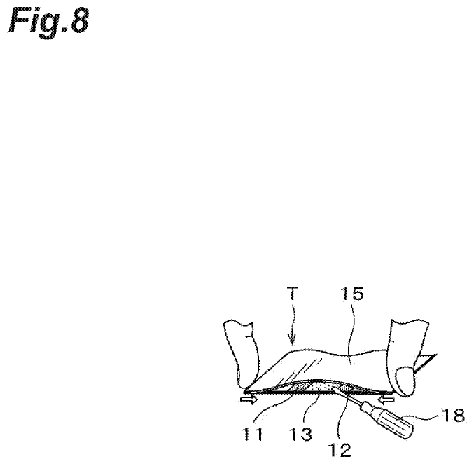

Note that the adhesion between the protective layer 15 and the base portion 10 also depends on the contact area between the lower surface of the protective layer 15 and the regions outside the conductive layers 11 and 12 on the surface of the base portion 10, that is, the sizes of the widths DN1 and DN2 illustrated in FIG. 3, and therefore, by adjusting the adhesive force of the surface of the base portion 10, the adhesive force of the lower surface of the protective layer 15, and the sizes of the widths DN1 and DN2 of the regions outside the conductive layers 11 and 12 on the surface of the base portion 10, an adhesive force in accordance with the width TW of the detection tape T can be obtained. For example, the adhesion widths DN1 and DN2 between the base portion 10 and the protective layer 15 may be made narrower than the width C1 of the conductive layer 11 and the width C2 of the conductive layer 12, or may be made narrower than the width N of the non-adhesive region 13. Furthermore, the width C1 of the conductive layer 11 and the width C2 of the conductive layer 12 may be set to be the same as the width N of the non-adhesive region 13. This makes it easier to create a gap in the center of the detection tape T, as will be described later with reference to FIGS. 7 and 8. Also, the width C1 of the conductive layer 11 and the width C2 of the conductive layer 12 may be set to be the same as or greater than the width N of the non-adhesive region 13. This may suppress noise from being superimposed on the conductive layers 11 and 12 during transmission and reception of pulse waves, which will be described later.

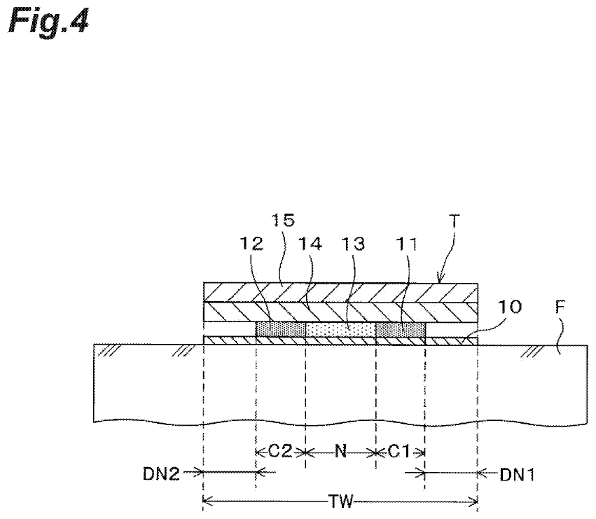

Note that the detection tape T illustrated in FIG. 3 described above has a configuration in which the insulating protective layer 15 is disposed on the conductive layers 11 and 12 and the non-adhesive region 13 so as to cover them, and the protective layer 15 directly adheres to the base portion 10, but the present disclosure is not limited to this, and the detection tape T illustrated in FIG. 4 can also be proposed. That is, the detection tape T illustrated in FIG. 4 has a configuration in which a double-sided adhesive layer 14 is provided on the lower surface of the protective layer 15. Therefore, the protective layer 15 adheres to the base portion 10 via this double-sided adhesive layer 14. Since the non-adhesive region 13 is located between the conductive layers 11 and 12, the double-sided adhesive layer 14 on the lower surface of the protective layer 15 and the non-adhesive region 13 do not adhere to each other, and this portion is peelable.

Also in the detection tape T illustrated in FIG. 4, the adhesive force of each portion is set such that the adhesion between the front surface side of the base portion 10 and the lower surface side of the double-sided adhesive layer 14 is stronger than the adhesion on the back surface side of the base portion 10, that is, the adhesion between the base portion 10 and the surface of the floor tile F. This may realize a configuration in which, as in the example described above, the base portion 10 of the detection tape T can be peeled from the surface of the floor tile F, but the protective layer 15 and the base portion 10 are not readily peeled from each other. Therefore, in the case of the detection tape T illustrated in FIG. 4 as well, it may readily be attached and detached to and from the surface of the floor tile F, and workability is good. Also, the protective layer 15 is not readily peeled from the base portion 10, and exposure of the internal conductive layers 11 and 12 is suppressed.

Of course, the adhesion between the protective layer 15 and the base portion 10 also depends on the contact area between the lower surface of the double-sided adhesive layer 14 on the lower surface of the protective layer 15 and the regions outside the conductive layers 11 and 12 on the surface of the base portion 10, that is, the sizes of the widths DN1 and DN2 illustrated in FIG. 4, and therefore, by adjusting the adhesive force of the surface of the base portion 10, the adhesive force of the lower surface of the double-sided adhesive layer 14, and the sizes of the widths DN1 and DN2 of the regions outside the conductive layers 11 and 12 on the surface of the base portion 10, an adhesive force in accordance with the width TW of the detection tape T can be obtained. As in the above case, the adhesion widths DN1 and DN2 between the base portion 10 and the protective layer 15 may be made narrower than the width C1 of the conductive layer 11 and the width C2 of the conductive layer 12, or may be made narrower than the width N of the non-adhesive region 13. Furthermore, the width C1 of the conductive layer 11 and the width C2 of the conductive layer 12 may be set to be the same as the width N of the non-adhesive region 13.

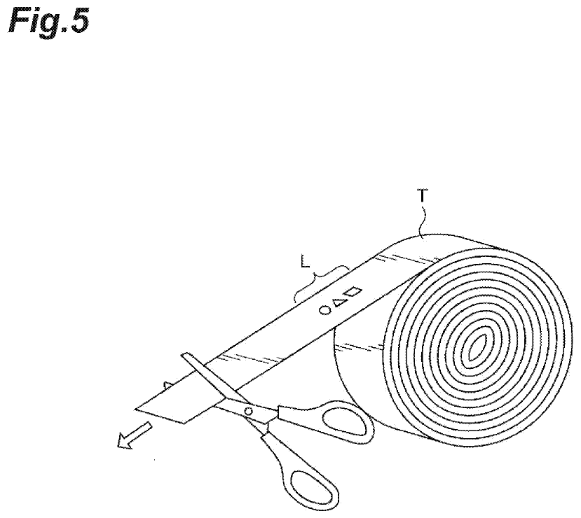

The detection tape T having such a configuration is wound in a roll as illustrated in FIG. 5, and can be paid out in the direction of the arrow in the figure when in use. The tape may then be cut at a desired length with, for example, scissors H or a knife. Therefore, for example, to arrange the detection tape T extending across floor tiles F2 to F4 as illustrated in FIG. 2, one end may be attached to the surface of one end of floor tile F2 while pulling out the length to be used, and the detection tape T may be cut at the other end portion of floor tile F4. Therefore, workability is extremely good. For example, even when arranging the detection tape T extending across a plurality of floor tiles F, the work can be performed simply and quickly. Note that, as illustrated in FIG. 5, in order for the detection tape T to be paid out from a roll-wound state, it is sufficient that the lower surface side of the base portion 10 has the property of being peelable from the surface of the protective layer 15.

Furthermore, in this example, on the front surface side of the protective layer of the detection tape T, as illustrated in FIG. 5, a logo mark L indicating, for example, the company name of the manufacturer or manager of the substrate processing apparatus 1 is displayed at predetermined intervals, for example, at intervals of approximately 10 cm to 50 cm. By displaying the logo mark L indicating the company name of the manufacturer or manager of the substrate processing apparatus 1 on the surface of the detection tape T in this way, when the detection tape T is arranged extending across a plurality of floor tiles F, persons entering the cleanroom recognize that something related to the substrate processing apparatus 1 exists on the floor tiles F. This suppresses unauthorized removal of the floor tiles F to create an open state or leaving such an open state unattended without the permission of the manager.

The detection tape T having the above configuration is attached and arranged extending across the surfaces of a plurality of floor tiles F as described above. In the example of FIG. 2, it is arranged extending across floor tiles F2 to F4. A controller 20 electrically connected to the conductive layers 11 and 12 is provided on one end side of the detection tape T arranged in this way, and at the other end side of the detection tape T, that is, the terminal end, the ends of the conductive layers 11 and 12 are electrically connected to each other. The controller 20 is provided with a transmitter, a receiver, a measuring unit, and an alarm unit, as will be described later, and these are controlled by a control unit.

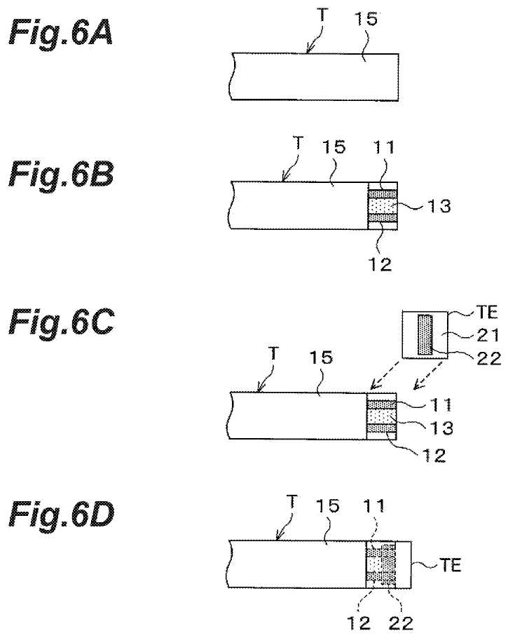

The work of electrically connecting the terminal ends of the conductive layers 11 and 12 in this way is performed, for example, by the procedure illustrated in FIGS. 6A to 6D. That is, at the end of the detection tape T already attached to the surface of the floor tile F as illustrated in FIG. 6A, the protective layer 15 at the end is cut without cutting the base portion 10, for example, by approximately 3 cm from the end, as illustrated in FIG. 6B. As described above, since the protective layer 15 adheres to the base portion 10, removing the protective layer 15 without removing the base portion 10 from a point 3 cm from the end is normally a laborious and troublesome task.

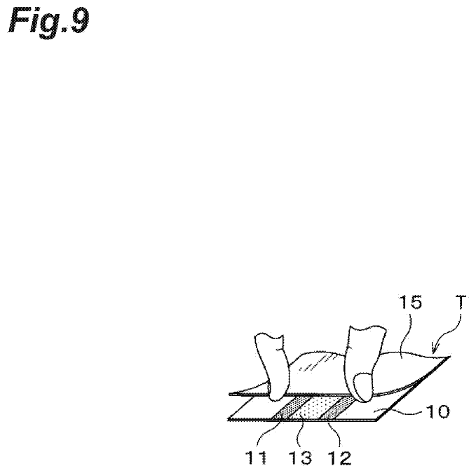

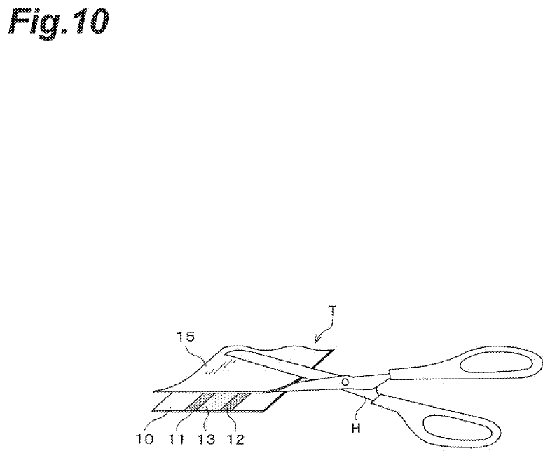

However, in the detection tape T of the present disclosure, as described above, the non-adhesive region 13 is located between the conductive layers 11 and 12, and the double-sided adhesive layer 14 on the lower surface of the protective layer 15 does not adhere to the non-adhesive region 13, and the double-sided adhesive layer 14 on the lower surface of the protective layer 15 is peelable from the non-adhesive region 13. Therefore, from the flat state of FIG. 7, if both sides of the protective layer 15 of the detection tape T are pressed inward (in the direction of the arrows in the figure) with fingers, for example, as illustrated in FIG. 8, the central portion of the detection tape T rises up and a gap is created as illustrated in the same figure. Then, when a thin object such as the tip of a screwdriver 18 as illustrated in the figure is inserted into this gap and the protective layer 15 is lifted, the gap becomes larger. Next, as illustrated in FIG. 9, the end of the protective layer 15 is peeled up with, for example, a finger. Then, the peeled-up state of the protective layer 15 at the end is maintained. After that, as illustrated in FIG. 10, the end of the peeled-up protective layer 15 may be cut with scissors H or a knife at a point of, for example, approximately 3 cm in length.

By the procedure described above, from the state of the detection tape T illustrated in FIG. 6A, the protective layer 15 at the terminal end is removed by, for example, approximately 3 cm as illustrated in FIG. 6B. After that, as illustrated in FIG. 6C, a connection tape TE dedicated to the terminal end may be attached onto the conductive layers 11 and 12 and the non-adhesive region 13 exposed at the end of the detection tape T.

This connection tape TE, as illustrated in FIG. 6C (note that in FIG. 6C, the connection tape TE is depicted as seen from the back surface side), has an adhesive layer 21 provided on a lower surface of an insulating protective layer 15, and a conductive layer 22 is provided on the lower surface of the adhesive layer 21 in a region narrower than the adhesive layer 21. The conductive layer 22 has a width and length sufficient to electrically connect the two conductive layers 11 and 12 at the terminal end of the detection tape T. By attaching such a connection tape TE onto the conductive layers 11 and 12 and the non-adhesive region 13 exposed at the terminal end of the detection tape T, the conductive layers 11 and 12 are electrically connected at the terminal end. A state in which the connection tape TE is attached to the end of the detection tape T is illustrated in FIG. 6D.

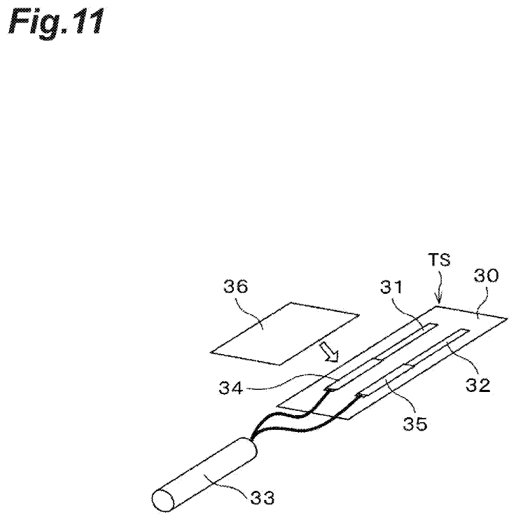

Note that, as illustrated in FIG. 2, a controller 20 electrically connected to the conductive layers 11 and 12 is provided on the starting end side of the detection tape T, and for the connection between the conductive layers 11 and 12 of the detection tape T and the controller 20, a connection tape TS serving as a start tape is used, for example, as illustrated in FIG. 11. FIG. 11 is a perspective view of the connection tape TS as seen from the back surface side, and conductive layers 31 and 32 electrically connected to the conductive layers 11 and 12 of the detection tape T are provided on an adhesive layer on a lower surface of an insulating protective layer 30. The conductive layers 31 and 32 are constituted by, for example, copper foil, similarly to the conductive layers 11 and 12.

By soldering, for example, lead portions 34 and 35 of a cable 33 connected to the controller 20 to the conductive layers 31 and 32, the conductive layers 11 and 12 of the detection tape T and the controller 20 can be electrically connected. An insulating protective tape 36, for example, may be attached to the connection points between the lead portions 34 and 35 and the conductive layers 31 and 32.

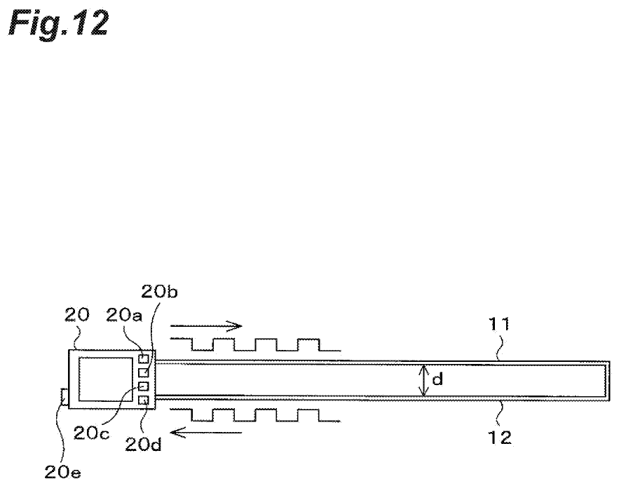

In the monitoring system M configured by arranging the detection tape T having the above configuration, as illustrated in FIG. 12, a pulse wave is transmitted from the transmitter 20a provided in the controller 20 to the conductive layer 11, and the pulse wave reaches the receiver 20b provided in the controller 20 via the conductive layer 12 from the terminal end of the detection tape T. Therefore, in this example, the conductive layer 11 in the detection tape T arranged on the floor tile F constitutes a transmission path, and the conductive layer 12 constitutes a reception path.

The controller 20 is provided with a measuring unit 20c that measures the pulse wave returning from the conductive layer 12 serving as the reception path, and a predetermined alarm or alarm signal is generated from the alarm unit 20d based on the measurement result from the measuring unit 20c.

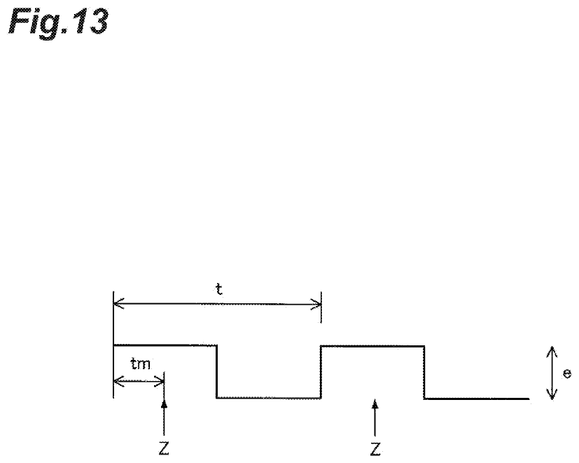

In this example, the oscillation frequency of the pulse wave is set to 1 kHz, and as illustrated in FIG. 13, the period t of the pulse wave is 1000 μS. Also, the voltage value e is set to 3 V. Further, the current value is set to 0.62 mA. The pulse wave from the reception path is measured by the measuring unit 20c, and at a measurement position Z, the voltage value at the ¼ wavelength point is measured as illustrated in FIG. 13. Then, when the voltage value, for example, at a delay time of 80 μS, falls below a predetermined threshold value, which is ½ of the rated value, that is, 1.5 V, it is determined that there is an abnormality, and a predetermined alarm or alarm signal is generated from the alarm unit 20d. Of course, when the signal itself cannot be received by the receiver 20b, an alarm or alarm signal is also generated. The transmitter 20a, receiver 20b, measuring unit 20c, and alarm unit 20d provided in the controller 20 are controlled by the control unit 20e provided in the controller 20.

In this way, in the monitoring system M of the present disclosure even if a noise voltage is picked up at the time of cutting the detection tape T since the voltage value is measured at the measurement position Z, monitoring can be performed because the threshold value is set to 1.5 V, which is ½ of the voltage value e. To describe in more detail, for example, when the total length of the detection tape T arranged in the monitoring system M is 60 m, it was confirmed that the voltage of the returning pulse measured on the reception path is approximately 2.8 V, which is not very low. Therefore, when setting the threshold value, with around 1.5 V (which is half of the oscillation voltage of 3 V) as a reference, the lower the threshold value, the weaker it becomes against noise, and conversely, the higher it becomes, the weaker it becomes against the voltage drop of the return itself. Thus, by setting the threshold value illustrated in this example to 1.5 V, the system may be strong against noise and also cope with voltage drops. Therefore, the cutting of the detection tape T can be suitably detected while suppressing the influence of noise. Of course, it can also be determined as abnormal when the return voltage itself is not detected. Furthermore, cases of improper use, such as when the conductive layers 11 and 12 are exposed, or when the connection portions between the conductive layers 11 and 12 are beginning to peel off, may also detected as abnormal.

Note that, as can also be seen from FIG. 12, the conductive layer 11 constituting the transmission path and the conductive layer 12 constituting the reception path are arranged in parallel in the detection tape T, but if, for example, a pulse wave of an extremely high frequency flows through the conductive layers 11 and 12, there is a risk that accurate measurement cannot be performed due to capacitive coupling. To prevent this, for example, the distance d between the conductive layer 11 and the conductive layer 12 (the width of the non-adhesive region 13) may be increased, but doing so increases the width of the detection tape T, which is disadvantageous in terms of handling and practicality.

On the other hand, in a cleanroom, there are many electrical machines and instruments using electric power at a commercial frequency of, for example, 50 Hz or 60 Hz, and many conductive paths and portions through which current at the commercial frequency flows. Further, in general, the floor tile F is made of a conductive material. Therefore, the pulse wave transmitted from the transmitter 20a may be set to a frequency high enough to be clearly distinguished from the commercial frequency without being affected by such commercial frequency.

From this perspective, in the example of the present disclosure, the oscillation frequency of the pulse wave is set to 1 kHz. Also, the width of the detection tape T is set to 40 mm, and the width of conductive layers 11 and 12, and the distance d between the conductive layers 11 and 12 (the width of the non-adhesive region 13) are set to 8 mm each. Of course, without being limited to this, a pulse wave having an oscillation frequency such that it does not propagate between the conductive layer 11 and the conductive layer 12 may be used in accordance with the distance d between the conductive layer 11 and the conductive layer 12.

Also, the reason why the current value of the pulse wave is set to 0.62 mA is as follows. That is, as will be described later, when lifting the floor tile F to create an opening for work purposes, the detection tape T arranged extending across a plurality of floor tiles F is cut with scissors, a cutter, or the like. This is because there is a risk that current may flow through the body of the worker via the scissors or cutter held in the worker's hand. In such a case, if the current value is large (for example, 5 mA or more), there is a risk that the worker's body may be endangered. Therefore, the current value of the pulse wave is set to 1 mA or less, which is generally considered to be within a safe range for the human body.

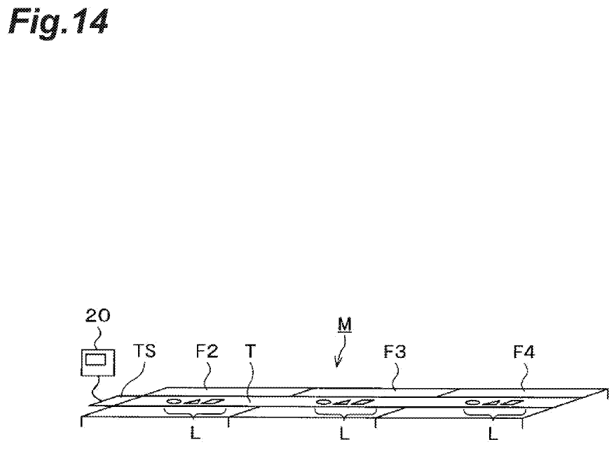

In the monitoring system M configured as described above, as illustrated in FIG. 14, in one detection tape T arranged extending across floor tiles F2 to F4, the logo mark L indicating the company name of the manufacturer or manager of the substrate processing apparatus 1 is displayed on the surface of the detection tape T as illustrated in the figure. Therefore, as described above, persons who have entered the cleanroom are prevented from arbitrarily removing the floor tiles F to create an open state or leaving such an open state unattended.

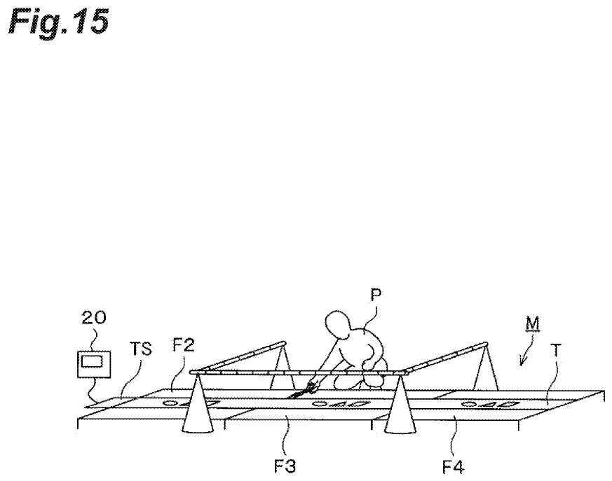

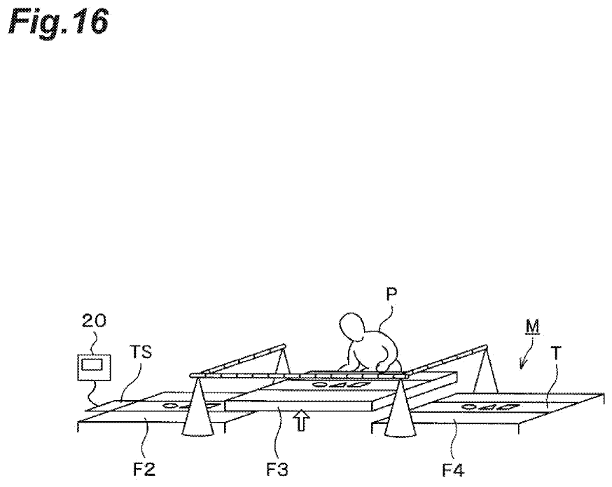

Incidentally, since one detection tape T is attached extending across floor tiles F2 to F4, when a worker P performs work in the space below the floor tile F, for example, the space below floor tile F3, the worker P first cuts the detection tape T at both end portions of floor tile F3 using scissors or a cutter as illustrated in FIG. 15. Then, after that, the floor tile F3 may be lifted as illustrated in FIG. 16.

As described above, in the monitoring system M, as illustrated in FIG. 12, a pulse wave is transmitted from the transmitter 20a of the controller 20 to the conductive layer 11 in the detection tape T, and the pulse wave returns to the receiver 20b of the controller 20 via the conductive layer 12. Further, since the measuring unit 20c of the controller 20 monitors the returning pulse wave, an alarm is generated at the point when the detection tape T is cut at both end portions of floor tile F3. Therefore, the worker P and other workers in the vicinity can recognize that an opening has been created at the floor tile F, and the safety of the workers can be improved.

Also, to construct such a monitoring system M, as described above, it is sufficient to attach the detection tape T extending across a plurality of floor tiles F. Moreover, since the detection tape T is wound in a roll as illustrated in FIG. 5, it can be readily paid out, and furthermore, since the back surface of the base portion on the lower surface of the detection tape T is adhesive, it is sufficient to attach the paid-out detection tape T directly to the surface of the floor tile F. Then, it is sufficient to cut the detection tape T at the terminal end portion of the floor tile F on which installation is to be performed. After that, the connection tape TE dedicated to the terminal end illustrated in FIG. 6 described above may be attached to the cut portion. Therefore, the monitoring system M can be readily constructed.

Incidentally, the detection tape T once cut as illustrated in FIGS. 15 and 16 is in a state where both the transmission path and the reception path are cut and the pulse wave does not flow, so when the predetermined work in the space below the floor tile F is completed, the removed floor tile F3 may be restored to its original position and electrically reconnect the transmission path and the reception path. Simply placing the floor tile F3 back in its original position does not allow the conductive layers 11 and 12 at the cut ends of the cut detection tape T to be connected.

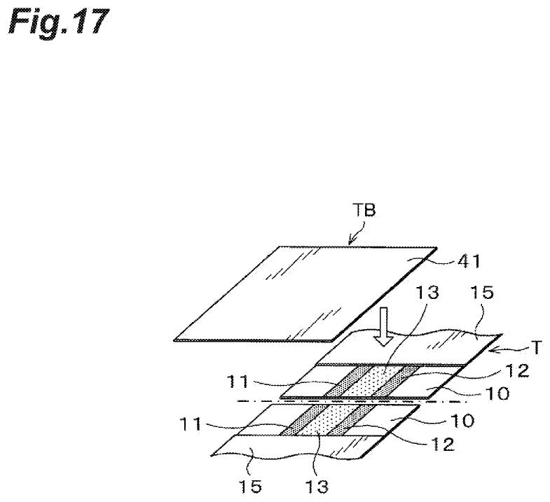

In such a case, first, as illustrated in FIG. 17, following the method illustrated in FIGS. 7 to 10 described above, the protective layer 15 at each end of the cut detection tape T is removed by, for example, approximately 3 cm, to expose the conductive layers 11 and 12. Note that the dashed-dotted line in the figure indicates the abutting end faces of the floor tiles F.

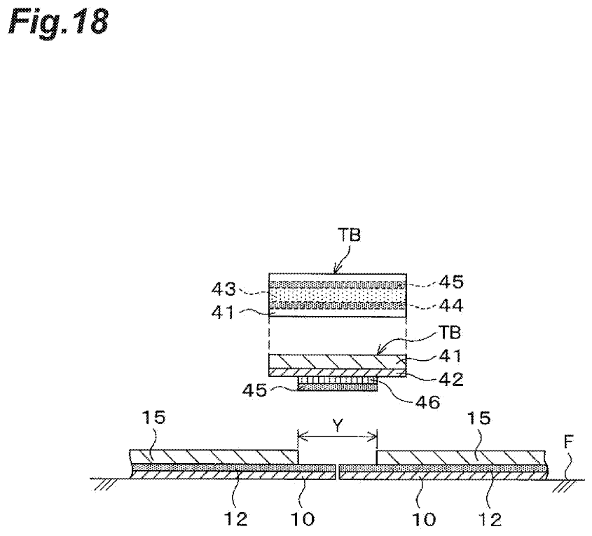

Next, the ends of the cut detection tape T are electrically connected to each other using a connection tape TB for reconnection having the structure illustrated in FIG. 18. This connection tape TB has an insulating protective layer 41 with an adhesive layer 42 provided on the lower surface thereof, and conductive layers 44 and 45 are provided in parallel on the lower surface of the adhesive layer 42 in a region narrower than the adhesive layer 42 with a non-adhesive region 43 interposed therebetween. An adjustment layer 46 for height adjustment is provided between the conductive layers 44 and 45 and the adhesive layer 42. Copper foil, for example, is used for the conductive layers 44 and 45. The length of the connection tape TB is longer than the opposing distance Y of the portion from which the protective layer 15 has been removed in the detection tape T attached on the floor tile F, and the length of the conductive layers 44 and 45 in the extending direction is equal to the distance Y.

As can also be seen from FIG. 18, the conductive layers 11 and 12 at the exposed end of the detection tape T from which the protective layer 15 at the end has been removed are to be reliably electrically connected to the conductive layers 44 and 45 located on the lower surface of the connection tape TB, but the length of the connection tape TB is longer than the opposing distance Y of the portion from which the protective layer 15 has been removed. Therefore, even if the connection tape TB is attached to the portion where the conductive layers 11 and 12 are exposed, there is a risk that the conductive layers 11 and 12 of the detection tape T and the conductive layers 44 and 45 of the connection tape TB may not be electrically connected.

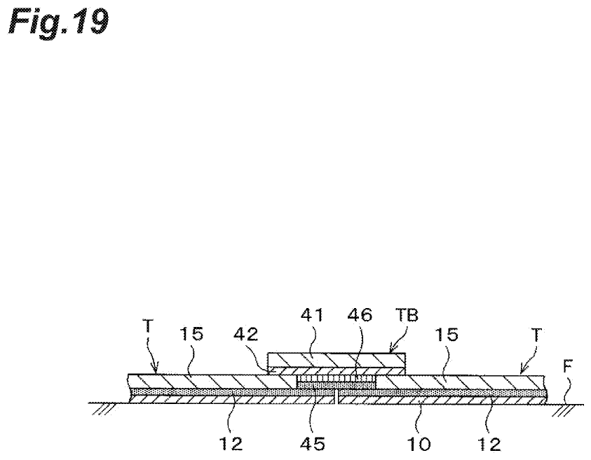

Therefore, the connection tape TB has the adjustment layer 46 for height adjustment between the conductive layers 44 and 45 and the adhesive layer 42. This makes it possible, when the connection tape TB is attached to the portion where the conductive layers 11 and 12 are exposed, to match the height of the protective layer 15 on the upper surface of the detection tape T with the combined thickness of the conductive layers 44 and 45 and the adjustment layer 46, as illustrated in FIG. 19, so that the conductive layers 11 and 12 and the conductive layers 44 and 45 of the connection tape TB are reliably electrically connected.

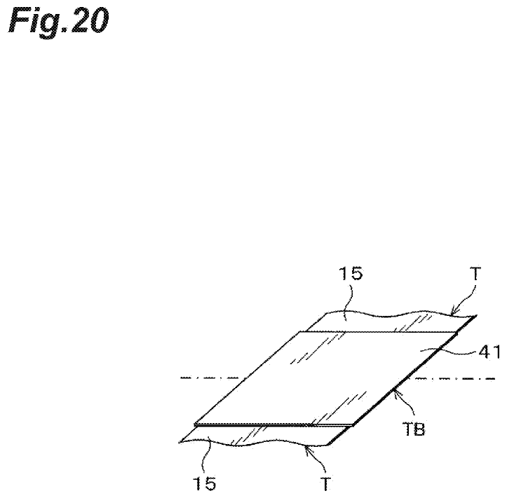

Note that when the connection tape TB is attached to the exposed portion of the conductive layers 11 and 12 of the detection tape T in this way, as also illustrated in FIG. 20, the end of the protective layer 41 of the connection tape TB becomes higher than the protective layer 15 on the upper surface of the detection tape T, creating a step as illustrated in the figure. However, even if such a step occurs, since the detection tape T and the connection tape TB themselves are flat in the first place, and the connection tape TB is attached on the protective layer 15 of the detection tape T via the adhesive layer 42 on the lower surface of the protective layer 41, considering that the floor tile F is normally walked on by people, there is no disadvantages caused by a step of that height.

The adjustment layer 46 described above may also be provided in the connection tape TE dedicated to the terminal end already described with reference to FIG. 6, and in the angle-shaped connection tape TC that changes direction by 90 degrees in plan view, which will be described later.

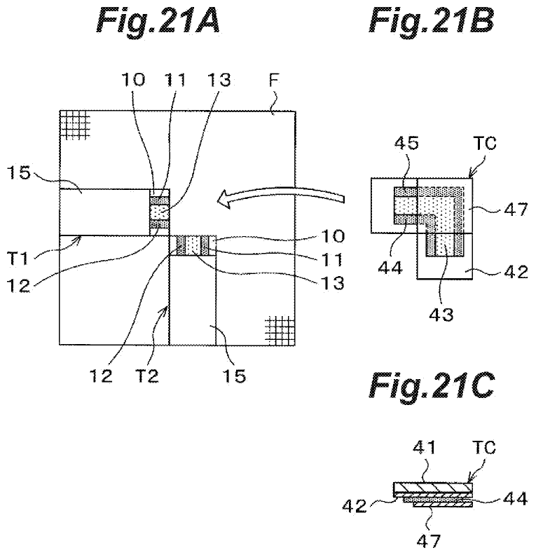

Incidentally, depending on the installation location of the monitoring system M, the detection tape T may be arranged on the floor tile F by bending the extending direction of the detection tape T at a right angle. FIG. 20 illustrates the measure in such a case. FIG. 21A illustrates a state in which the protective layer 15 at each end of two detection tapes T1 and T2 arranged extending in mutually perpendicular directions on the floor tile F has been removed by a predetermined length from the end, for example, approximately 3 cm. As illustrated in the figure, the conductive layers 11 and 12 at each end of the detection tapes T1 and T2 are exposed. Note that to remove the protective layer 15 at each end of the two detection tapes T1 and T2 by a predetermined length from the end in this way, the method illustrated in FIGS. 7 to 10 described above may be followed.

For electrically connecting the conductive layers 11 and 12 at the so-called corner portions of the detection tape T arranged to bend at a right angle in this way, a connection tape TC illustrated in FIG. 21B is used. FIG. 21B is a view of the connection tape TC as seen from the back surface side, and FIG. 21C is a side cross-sectional view of the connection tape TC.

As can be seen from these figures, the connection tape TC has an insulating protective layer 41 with an adhesive layer 42 provided on the lower surface thereof, and two conductive layers 44 and 45 are provided in parallel on the lower surface of the adhesive layer 42 in a region narrower than the adhesive layer 42 with a non-adhesive region 43 interposed therebetween. Copper foil, for example, is used for the conductive layers 44 and 45. The conductive layers 44 and 45 are provided on an insulating base portion 47 having adhesive properties on the front and back surfaces. Further, the conductive layers 44 and 45 are angle-shaped, changing direction by 90 degrees in plan view.

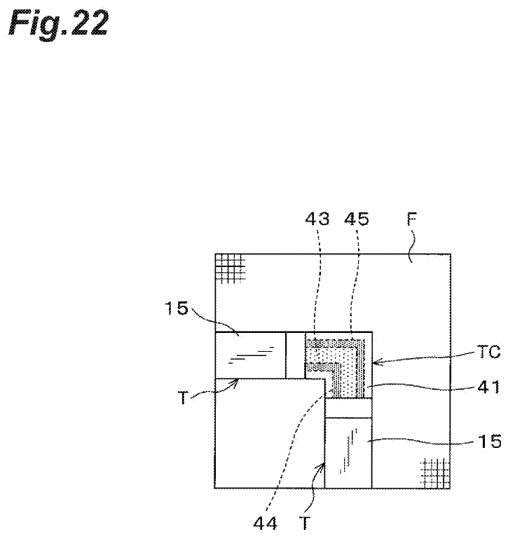

By attaching the connection tape TC having such a configuration to the corner portion of the detection tape T on the floor tile F where the conductive layers 11 and 12 are exposed, as illustrated in FIG. 22, the conductive layers 44 and 45 of the connection tape TC may electrically be connected to the exposed conductive layers 11 and 12 at each end of the detection tapes T1 and T2. Therefore, workability is extremely good. Since the insulating base portion 47 is located at the corner of the lower surface of the connection tape TC, the conductive layers 44 and 45 do not come into direct contact with the floor tile F.

In the example described above, in addition to the basic detection tape T that can be wound in a roll, for example, a connection tape TS serving as a start tape used for connection to the controller 20, a connection tape TB used for reconnection, a connection tape TE dedicated to the terminal end, and a connection tape TC used when changing direction by 90 degrees in plan view are prepared, so there is flexibility in the installation of the monitoring system, and a suitable monitoring system can be constructed in accordance with the apparatus installed in the cleanroom and its installation conditions.

In the example described above, a pulse wave is passed through the detection tape T, and the presence or absence of an opening caused by the removal of the floor tile F is detected by comparing the voltage value of the pulse wave measured on the reception path with a preset threshold value and by the presence or absence of the pulse wave. As an alternative to this, the impedance of the conductive layers 11 and 12 may be constantly monitored, and when the impedance changes significantly beyond a set threshold value, it may be determined that the floor tile F has been removed and an opening has occurred.

To describe in more detail, in order to detect an abnormality based on a change in impedance, the system may be configured such that, after setting the detection tape T, for example, the variable resistance of the bridge circuit in the controller 20 is adjusted to match the impedance of the line so that the bridge circuit is in a balanced state (calibration), and an abnormality is detected when the conductive layers 11 and 12 of the detection tape T become disconnected and the balance of the circuit is disrupted.

All of the above disclosure are illustrative in all respects and are not restrictive. The above disclosure may be omitted, substituted, or modified in various forms without departing from the scope and spirit of the appended claims.

Note that the following configurations belong to the technical scope of the present disclosure. Configurations combining the matters described in (1) to (15) below within a consistent range also belong to the technical scope of the present disclosure.
(1) A monitoring system for monitoring surroundings of a substrate processing apparatus installed in a cleanroom, the monitoring system including: a detection tape disposed on upper surfaces of some or all of the floor tiles surrounding the substrate processing apparatus, the detection tape extending across a plurality of floor tiles, wherein the detection tape includes a conductive layer disposed along a longitudinal direction of the tape, and wherein the monitoring system further includes an alarm unit configured to generate an alarm when electrical continuity in the conductive layer is interrupted or when a voltage of a signal current flowing through the conductive layer falls below a predetermined threshold value.
(2) The monitoring system according to (1), wherein the conductive layer includes a transmission path and a reception path.
(3) The monitoring system according to (2), wherein the alarm unit is connected to one end of each of the transmission path and the reception path, and wherein the other ends of the transmission path and the reception path are electrically connected to each other.
(4) The monitoring system according to (3), wherein the other ends of the transmission path and the reception path are electrically connected via an angle-shaped connection tape that changes direction by 90 degrees in plan view.
(5) The monitoring system according to (4), including: a transmitter configured to transmit a pulse signal to the transmission path; a receiver configured to receive a pulse signal from the reception path; and a measuring unit configured to measure a pulse signal from the reception path.
(6) The monitoring system according to (5), wherein the monitoring system is configured to generate the alarm when the pulse signal is not received, or when the pulse signal from the reception path measured by the measuring unit falls below a predetermined threshold value.
(7) The monitoring system according to (6), wherein the pulse signal has a current value of 1 mA or less.
(8) The monitoring system according to (6) or (7), wherein the pulse signal has a frequency at which the pulse signal does not propagate between the transmission path and the reception path.
(9) The monitoring system according to (1), wherein the alarm unit is configured to generate an alarm based on a change in impedance in the conductive layer.
(10) The monitoring system according to any one of (1) to (7) and (9), wherein the detection tape includes: an insulating base portion including insulating adhesive layers on a front surface and a back surface; a conductive layer provided on the front surface of the base portion and disposed along the longitudinal direction of the detection tape; an insulating non-adhesive region disposed in contact with or in proximity to the conductive layer along the longitudinal direction of the detection tape; and an insulating protective layer covering the conductive layer and the non-adhesive region and adhering to the base portion, wherein the detection tape is configured to be paid out from a roll-wound state.
(11) The detection tape for a monitoring system according to (10), wherein adhesion between the base portion and the protective layer is provided by an insulating double-sided adhesive member disposed on a lower surface of the protective layer.
(12) A monitoring method for monitoring surroundings of a substrate processing apparatus installed in a cleanroom, the method comprising arranging, on upper surfaces of some or all of floor tiles surrounding the substrate processing apparatus, a detection tape so as to extend across a plurality of floor tiles, the detection tape including a conductive layer along a longitudinal direction of the tape, and generating an alarm when electrical continuity in the conductive layer is interrupted or when a voltage of a signal current flowing through the conductive layer falls below a predetermined threshold value.
(13) The monitoring method according to (12), wherein determining whether the electrical continuity in the conductive layer is interrupted is performed by presence or absence of reception of a signal current flowing through the conductive layer, or by comparison of a measured value of the signal current with a predetermined threshold value.
(14) The monitoring method according to (13), wherein the signal current is a pulse wave.
(15) A monitoring apparatus for monitoring surroundings of a substrate processing apparatus installed in a cleanroom, the monitoring apparatus including: a detection tape disposed on upper surfaces of some or all of the floor tiles surrounding the substrate processing apparatus, the detection tape extending across a plurality of floor tiles and including a conductive layer disposed along a longitudinal direction thereof; and an alarm unit configured to generate an alarm when electrical continuity in the conductive layer is interrupted or when a voltage of a signal current flowing through the conductive layer falls below a predetermined threshold value.
(16) A detection tape used in the monitoring system of (1), the detection tape including: an insulating base portion having insulating adhesive layers on a front surface and a back surface; a conductive layer provided on the front surface of the base portion and disposed along a longitudinal direction of the detection tape; an insulating non-adhesive region disposed in contact with or in proximity to the conductive layer along the longitudinal direction of the detection tape; and an insulating protective layer covering the conductive layer and the non-adhesive region and adhering to the base portion, and
wherein the detection tape is configured to be paid out from a roll-wound state.

It is to be understood that not all aspects, advantages and features described herein may necessarily be achieved by, or included in, any one particular example. Indeed, having described and illustrated various examples herein, it should be apparent that other examples may be modified in arrangement and detail.

What is claimed is:

1. A monitoring system for monitoring surroundings of a substrate processing apparatus installed in a cleanroom, the monitoring system comprising:
a detection tape disposed on upper surfaces of some or all of floor tiles surrounding the substrate processing apparatus, the detection tape extending across a plurality of floor tiles,
wherein the detection tape comprises a conductive layer disposed along a longitudinal direction of the tape, and
wherein the monitoring system further comprises a controller configured to generate an alarm based on electrical continuity in the conductive layer.

2. The monitoring system according to claim 1, wherein the controller is configured to generate the alarm in response to an abnormality in the electrical continuity in the conductive layer.

3. The monitoring system according to claim 2, wherein the controller is configured to detect the abnormality based on a voltage of a signal transmitted via the conductive layer.

4. The monitoring system according to claim 1, wherein the conductive layer comprises a transmission path and a reception path each extending along the longitudinal direction of the detection tape.

5. The monitoring system according to claim 4, wherein the controller is connected to one end of each of the transmission path and the reception path, and
wherein other ends of the transmission path and the reception path are electrically connected to each other.

6. The monitoring system according to claim 5, wherein the transmission path and the reception path extend from the controller to the other ends via an angle-shaped connection tape that changes direction of the transmission path and the reception path by 90 degrees in plan view.

7. The monitoring system according to claim 5, wherein the controller is further configured to:
transmit a pulse signal to the transmission path;
receive a pulse signal from the reception path; and
generate the alarm based on the received pulse signal.

8. The monitoring system according to claim 7, wherein the controller is further configured to:
detect an abnormality in the electrical continuity in the conductive layer based on the received pulse signal; and
generate the alarm in response to detecting the abnormality.

9. The monitoring system according to claim 7, wherein the controller is configured to generate the alarm in response to determining that the pulse signal is not received from the reception path, or the received pulse signal falls below a predetermined threshold value.

10. The monitoring system according to claim 7, wherein the pulse signal has a current value of 1 mA or less.

11. The monitoring system according to claim 8, wherein the pulse signal has a frequency at which the pulse signal does not propagate between the transmission path and the reception path to an extent that prevents detection of the abnormality in the electrical continuity.

12. The monitoring system according to claim 1, wherein the controller is configured to:
detect an impedance in the conductive layer; and
generate the alarm based on a change in the detected impedance.

13. The monitoring system according to claim 1, wherein the detection tape comprises:
an insulating base portion comprising insulating adhesive layers on a front surface and a back surface;
the conductive layer provided on the front surface of the base portion and disposed along the longitudinal direction of the detection tape;
an insulating non-adhesive region disposed on the front surface of the base portion along the longitudinal direction of the detection tape; and
an insulating protective layer covering the conductive layer and the non-adhesive region and adhering to the base portion,
wherein the detection tape is configured to be paid out from a roll-wound state.

14. The monitoring system according to claim 13, wherein the conductive layer comprises a transmission path and a reception path each extending along the longitudinal direction of the detection tape, and
the non-adhesive region is disposed between the transmission path and the reception path.

15. The monitoring system according to claim 13, wherein the protective layer adheres to the base portion via an insulating double-sided adhesive member.

16. A monitoring apparatus for monitoring surroundings of a substrate processing apparatus installed in a cleanroom, the monitoring apparatus comprising a controller configured to be connected to a detection tape disposed on upper surfaces of some or all of floor tiles surrounding the substrate processing apparatus, the detection tape extending across a plurality of floor tiles and comprising a conductive layer disposed along a longitudinal direction thereof,
wherein the controller is configured to generate an alarm based on electrical continuity in the conductive layer.

17. The monitoring apparatus according to claim 16, wherein the controller is configured to generate the alarm in response to an abnormality in the electrical continuity in the conductive layer.

18. The monitoring apparatus according to claim 17, wherein the controller is configured to detect the abnormality based on a voltage of a signal transmitted via the conductive layer.

19. A detection tape used in a monitoring system for monitoring surroundings of a substrate processing apparatus installed in a cleanroom,
wherein the monitoring system includes a controller configured to generate an alarm based on electrical continuity in a conductive layer of the detection tape,
wherein the detection tape is disposed on upper surfaces of some or all of floor tiles surrounding the substrate processing apparatus and extends across a plurality of floor tiles,
wherein the detection tape comprises:
an insulating base portion comprising insulating adhesive layers on a front surface and a back surface;
the conductive layer provided on the front surface of the base portion and disposed along a longitudinal direction of the detection tape;
an insulating non-adhesive region disposed on the front surface of the base portion along the longitudinal direction of the detection tape; and
an insulating protective layer covering the conductive layer and the non-adhesive region and adhering to the base portion, and
wherein the detection tape is configured to be paid out from a roll-wound state.

20. The detection tape according to claim 19, wherein the conductive layer comprises a transmission path and a reception path each extending along the longitudinal direction of the detection tape, and
the non-adhesive region is disposed between the transmission path and the reception path.
